(19) United States
(12) Patent Application Publication
(10) Pub. No.: US 2026/0170210 A1
(43) Pub. Date: Jun. 18, 2026

(54) COMPONENTS PARTITIONING METHOD, COMPUTER READABLE RECORDING MEDIA, AND ELECTRONIC APPARATUS

(71) Applicant: Industrial Technology Research Institute, Hsinchu (TW)

(72) Inventors: Yung-Chang Chen, New Taipei City (TW); Shih-Hsien Wu, Taoyuan City (TW)

(73) Assignee: Industrial Technology Research Institute, Hsinchu (TW)

(21) Appl. No.: 18/984,887

(22) Filed: Dec. 17, 2024

(51) Int. Cl. G06F 30/323; G06F 30/337

(52) U.S. Cl. CPC G06F 30/323; G06F 30/337

(57) ABSTRACT

Provided is a components partitioning method, which is adapted to partition multiple electronic components in a circuit diagram. The electronic components include multiple main components and multiple auxiliary components. The components partitioning method includes: the main components, a main component combination, and the auxiliary components are searched based on a netlist; at least one boundary condition is set; and the main components and the auxiliary components are partitioned based on the boundary condition and the netlist. A boundary condition between each component group meets a set value.

### TECHNICAL FIELD

The disclosure relates to a components partitioning method, a computer readable recording medium and an electronic apparatus.

### BACKGROUND

Generally speaking, the circuit design process includes a design stage, a verification stage, a manufacturing stage and a testing stage. The design stage includes the design of a physical circuit. During the design process of the physical circuit, the components in the circuit may be partitioned to facilitate subsequent distribution planning between modules, specific locations of the components, and the physical shape and interconnection of the circuit.

In addition, heterogeneous integrated packaging is an important development technology for semiconductor performance. Fast circuit partitioning technology contributes to heat dissipation efficiency planning, packaging area planning, and execution schedule planning for improving circuit performance of heterogeneous integrated packaging.

### SUMMARY

A components partitioning method according to the embodiment of the disclosure is adapted to partition electronic components in a circuit diagram. The electronic components include multiple main components and multiple auxiliary components. The components partitioning method includes: the main components, a main component combination and the auxiliary components are searched based on a netlist; at least one boundary condition is set; and the main components and the auxiliary components are partitioned based on the boundary condition and the netlist. A boundary condition between each component group meets a set value.

A computer readable recording medium according to the embodiment of the disclosure includes a computer program, which commands a computer to execute the foregoing components partitioning method after executing the computer program.

An electronic apparatus according to the embodiment of the disclosure is adapted to partition multiple electronic components in a circuit diagram. The electronic components include multiple main components and multiple auxiliary components. The electronic apparatus includes a storage component and a processor. The storage component is configured to store a computer program. The processor is configured to search for the main components, a main component combination and the auxiliary components based on a netlist after executing the computer program, set at least one boundary condition, and partition the main components and the auxiliary components based on the boundary condition and the netlist. A boundary condition between each component group meets a set value.

In order to make the features and advantages of the disclosure more comprehensible, the following examples are given and described in detail with the accompanying drawings as follows.

### BRIEF DESCRIPTION OF THE DRAWINGS

FIG. 1 is a schematic block diagram of an electronic apparatus according to an embodiment of the disclosure.

FIG. 2 is a step flow chart of a components partitioning method according to an embodiment of the disclosure.

FIG. 3 is a circuit block diagram of an embodiment of the disclosure.

FIG. 4 is a schematic outline diagram of a circuit board according to an embodiment of the disclosure.

FIG. 5 is a step flow chart of a search method of a main component according to an embodiment of the disclosure.

FIG. 6 is a flow chart of computation of a component sensitivity according to an embodiment of the disclosure.

FIG. 7 is a step flow chart of a search method of a main component combination according to an embodiment of the disclosure.

FIG. 8A and FIG. 8B are respectively schematic outline diagrams of different main component combinations in the embodiment of FIG. 7.

FIG. 9 is a step flow chart of a search method of a combination of a main component and an auxiliary component according to an embodiment of the disclosure.

FIG. 10 is a schematic outline diagram of main components located in different circuit layers according to an embodiment of the disclosure.

FIG. 11 is a schematic outline diagram where sensitive components are divided in a same layer according to an embodiment of the disclosure.

FIG. 12 is a schematic outline diagram of an embodiment of a boundary condition according to the disclosure.

FIG. 13 is a schematic outline diagram of another embodiment of a boundary condition according to the disclosure.

### DETAILED DESCRIPTION OF DISCLOSURED EMBODIMENTS

Embodiments are provided below to describe the disclosure in detail, though the disclosure is not limited to the provided embodiments, and the provided embodiments can be suitably combined. The term “coupling/coupled” or “connecting/connected” used in the specification (including claims) of the disclosure may refer to any direct or indirect connection means. For example, “a first component is coupled to a second component” should be interpreted as “the first component is directly connected to the second component” or “the first component is indirectly connected to the second component through other devices or connection means.” In addition, the term “signal” may refer to a current, a voltage, a charge, a temperature, data, electromagnetic wave or any one or multiple signals.

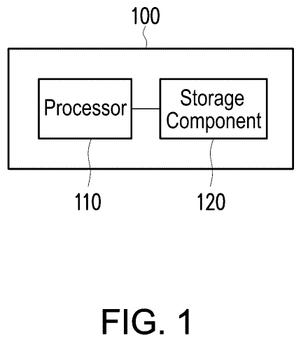

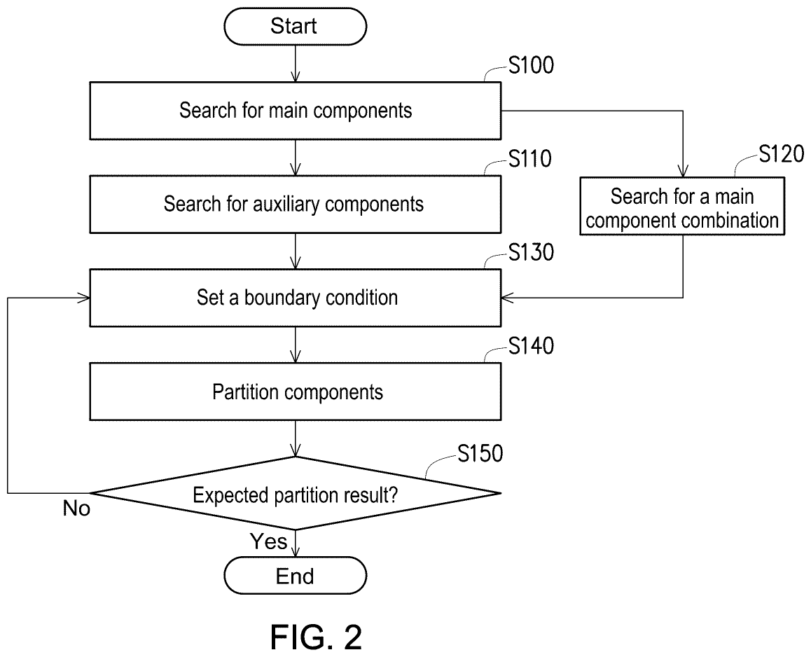

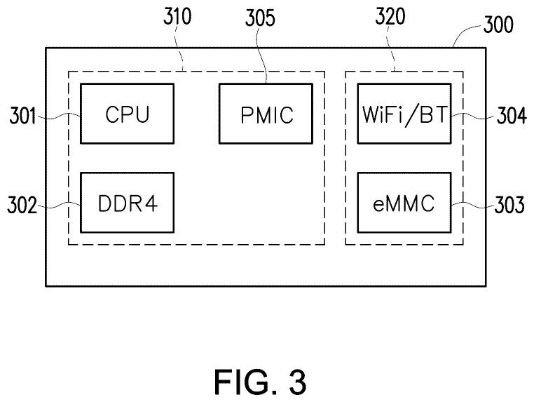

FIG. 1 is a schematic block diagram of an electronic apparatus according to an embodiment of the disclosure. FIG. 2 is a step flow chart of a components partitioning method according to an embodiment of the disclosure. FIG. 3 is a circuit block diagram of an embodiment of the disclosure. Please refer to FIG. 1 to FIG. 3. An electronic apparatus 100 is configured to execute the components partitioning method in FIG. 2 to divide multiple components 301 to 305 in a circuit diagram 300 into multiple groups.

The circuit block diagram shown in FIG. 3 is, for example, the circuit diagram 300 that has completed a functional design, including the multiple electronic components 301 to 305 and connecting lines between the electronic components. For the purpose of brevity, the connecting lines between other auxiliary components and the electronic components 301 to 305 are not shown in FIG. 3. The quantity, type and configuration relationship of the electronic components are used for illustration and are not used to limit the disclosure.

The electronic apparatus 100 includes a processor 110 and a storage component 120. The electronic apparatus 100 is, for example, a computer or other host system. The storage component 120 is, for example, a computer readable recording medium, including a computer program, which commands the computer to execute the components partitioning method in FIG. 2 after executing the computer program.

Specifically, in steps S100, S110, and S120, the processor 110 searches for the main components 301 to 305, an auxiliary component and a combination of the main components 301 to 305 based on a netlist and a component dimension table. The processor 110 may, for example, convert the circuit diagram 300 into the netlist, and obtain the quantity of connecting lines between each component based on the connection relationship of the netlist. The circuit diagram 300 uses graphic images to represent the connection relationships between each component; the netlist uses texts to describe the connection relationships between each component.

In the embodiment, the main components 301, 302, 303, 304, and 305 are, for example, respectively a central processing unit (CPU), a double-data-rate fourth generation synchronous dynamic random access memory (DDR4 SDRAM), an embedded multimedia card (eMMC), a WiFi or bluetooth communication module, and a power management IC (PMIC). The types of components are not used to limit the disclosure.

Next, in step S130, the processor 110 sets at least one boundary condition to partition the main components 301 to 305 and the auxiliary components in step S140. In step S150, the processor 110 may confirm whether the component partition result meets the expected result. If the component partition result meets the expected result, the processor 110 may end the components partitioning method in FIG. 2. If the component partition result does not meet the expected result, the processor 110 may return to step S130, reset the boundary condition and perform the components partitioning again (step S140). In an embodiment, the component partition result is, for example, dividing the main components 301, 302, and 303 into a first component group 310 and dividing the main components 304 and 305 into a second component group 320 to allow the two groups to have a smaller number of connections between each other. The disclosure does not limit the types of components included in each component group.

In the embodiment, the components partitioning method is enumeration, but is not limited thereto. Focusing on all main components, all partition combinations that meet the boundary condition are listed.

Therefore, the components partitioning method of the disclosure may quickly and effectively assist users to complete a modular circuit partition planning through a computer program. Heterogeneous integrated packaging is an important technology for semiconductor performance. Fast circuit partition technology contributes to heat dissipation efficiency planning, packaging area planning, and execution schedule planning for improving circuit performance of heterogeneous integrated packaging.

In an embodiment, the processor 110 is, for example, a central processing unit (CPU), or other programmable general-purpose or special-purpose micro control units (MCU), a microprocessor, a digital signal processor (DSP), a programmable controller, an application specific integrated circuit (ASIC), a graphics processing unit (GPU), an image signal processor (ISP), an image processing unit (IPU), an arithmetic logic unit (ALU), a complex programmable logic device (CPLD), a field programmable gate array (FPGA) or other similar components or a combination of the foregoing components.

In an embodiment, the storage component 120 is configured to store various software, data and various program codes needed during the operation of the components partitioning method. The storage component 120 is, for example, any type of fixed or movable random access memory (RAM), read-only memory (ROM), flash memory, hard disk drive (HDD), solid state drive (SSD) or similar components or a combination of the foregoing components, which is configured to store multiple modules or various applications that may be executed by the processor 110. In an embodiment, the storage component 120 may further include a database.

In an embodiment, the components partitioning method of the disclosure may be applied on an evaluation board (EVB) to select suitable components to partition to compose a system-on-module (SoM) and reduce the dimension of the circuit board. In an embodiment, the components partitioning method of the disclosure may be applied to heterogeneous integrated packaging of multi-chiplets, partitioning the chiplets to appropriately allocate input and output solder joints, such as μ-bumps of a ball grid array (BGA). The disclosure does not limit the levels of application.

The components partitioning method of the disclosure includes a setting method of a boundary condition, a search method of a main component, a search method of a main component combination, and a search method of a combination of a main component and an auxiliary component.

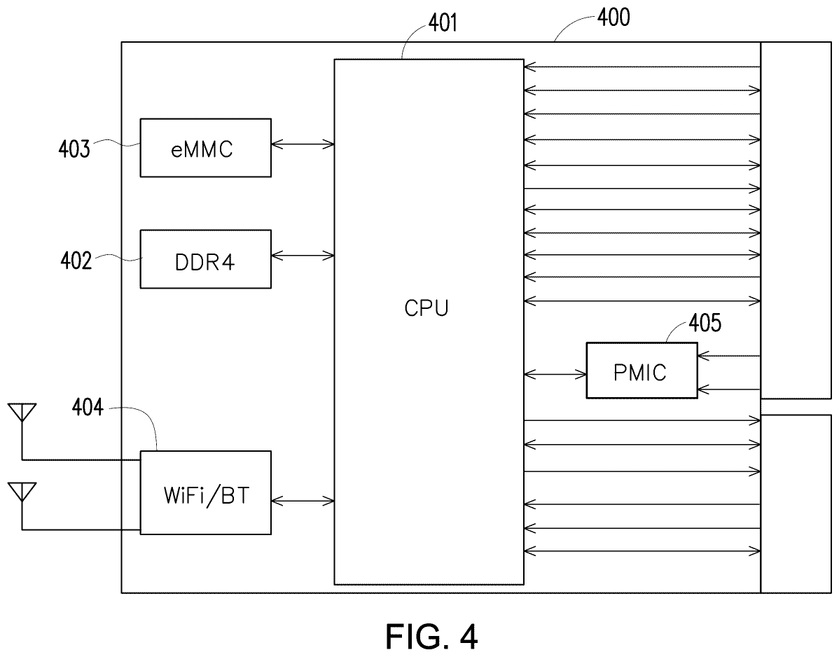

First, the setting method of a boundary condition is illustrated. FIG. 4 is a schematic outline diagram of a circuit board according to an embodiment of the disclosure. Please refer to FIG. 1 and FIG. 4. The electronic apparatus 100 may also partition multiple components in a circuit board 400 through the components partitioning method of the disclosure. In the embodiment, the processor 110 classifies components 401 to 405 as main components. Each main component may have a compatible auxiliary component. The auxiliary component is, for example, a resistor, a capacitor, and/or an inductor. The processor 110 uses the circuit layering method (that is, the components partitioning method of the disclosure, one of the embodiments with a circuit layer as a group) to determine which main components and auxiliary components are to be configured for each circuit layer to allow the number of connections between each layer to be optimized. For example, the processor 110 may optimize the number of connections between each circuit layer based on at least one boundary condition.

A first boundary condition is a boundary condition related to the number of connections. The netlist is served as an input. The processor 110 may receive the netlist to determine which main components and auxiliary components are to be configured for each circuit layer. Users may input the number of connections to be set through an input and output interface of the electronic apparatus 100. The number of connections may be set as a maximum number of connections, a minimum number of connections, or a number of connections within a preset range. For example, for a power delivery/distribution network with different needs of power consumption, different numbers of connections are set between layers. The processor 110 may configure the circuit components in layers accordingly to allow the circuit to meet a voltage or current supply demanded for the specification.

A second boundary condition is a boundary condition related to the separation and union of components. In the first boundary condition, the second boundary condition may be further used to allow the circuit to satisfy the needs of different modular applications. For example, components with a strong-coupling differential signal relationship need to be adjacently disposed to reduce the number of connections. On the contrary, components with a weak-coupling differential signal relationship may not be adjacently disposed. The processor 110 may compute the number of connections of components under various separation sets and union sets through logic computations such as intersection (AND), union (OR), or exclusion (NOT).

A third boundary condition is a boundary condition related to the partition area. System modules and package dimensions are usually customized or follow common standards. System module standards include, for example, but are not limited to OSM (Open Standard Module), SMARC (Smart Mobility ARChitecture), Qseven, COM Express and other common standards. Users may set the system module and the package dimension by themselves to set the boundary condition of the partition area.

Therefore, the boundary conditions in the embodiment includes conditions such as the number of connections, the separation and union of components, and the partition area. The processor 110 may optimize the number of connections between each circuit layer based on at least one of the foregoing boundary conditions to allow the circuit to meet various demands.

In the embodiment, the set values that the boundary condition between each component group meets include a set value of the area, a set value of the number of connections, and a set value of the separation and union of components. The set value of the area may be specified by the user, or a default balance value, or a minimum value. The set value of the number of connections may be specified by the user, or a maximum value or a minimum value. The set value of the separation and union of the components may be specified by the user or not.

Although the embodiment takes three boundary conditions as an example, the disclosure is not limited thereto. The quantity of boundary conditions is not intended to limit the disclosure. In other implementations, users may set more boundary conditions by themselves.

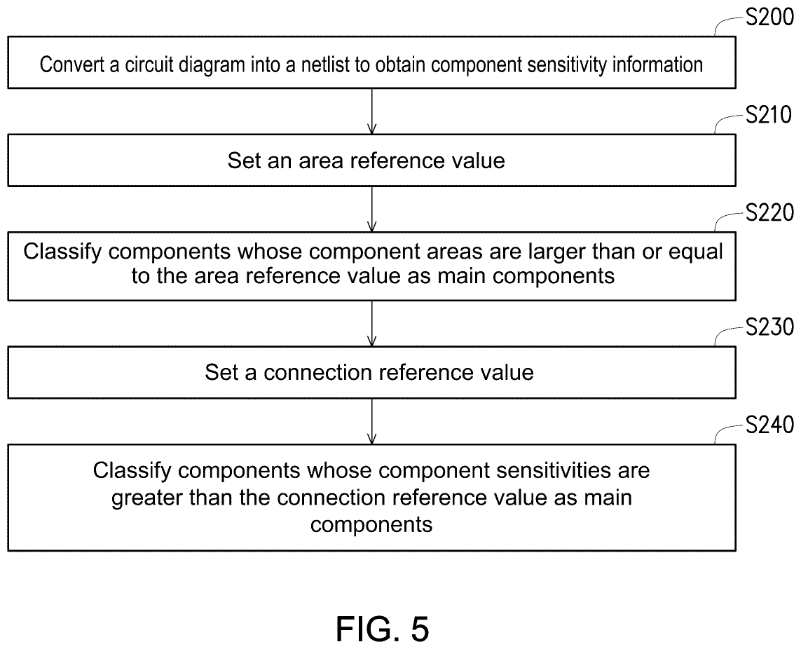

Next, the search method for the main component is illustrated. FIG. 5 is a step flow chart of a search method of a main component according to an embodiment of the disclosure.

Please refer to FIG. 1, FIG. 3 and FIG. 5. The embodiment uses the circuit diagram 300 in FIG. 3 as an example to illustrate the search method of the main component, but the disclosure is not limited thereto.

In the embodiment, the processor 110 determines whether the component is a main component based on the number of connections between components and the component areas.

The component dimension table includes information of the component areas. For example, the processor 110 classifies a component whose component area is larger than an area reference value as a main component. Alternatively, the processor 110 classifies a component whose component area is smaller than the area reference value and whose number of connections between components is greater than a connection reference value as a main component. The connection reference value and the area reference value may be set by the user.

Specifically, Table 1 below is a netlist converted based on the circuit diagram 300. The component sensitivity is the number of connections between components, that is, the sum of the quantities of connections between each component and other components. The component sensitivity represents the number of connections between each component and other components. High sensitivity represents that the number of connections between a target component and other components is greater. Low sensitivity represents that the number of connections between the target component and other components is less.

TABLE 1

| | | Component | Component |
|---|---|---|---|
| Number | Type of Component | Sensitivity | Area |
| 1 | CPU | 277 | 129.8 |
| 2 | DDR4 | 75 | 150 |
| 3 | First Connector | 61 | 200 |
| 4 | Second Connector | 57 | 200 |
| 5 | WiFi/BT | 33 | 100 |
| 6 | eMMC | 15 | 149.5 |
| 7 | PMIC | 119 | 38.4 |
| 8 | ON/OFF Circuit | 5 | 1 |
| 9 | First Duplexer | 4 | 3 |
| 10 | Low Dropout Regulator | 3 | 8.12 |
| 11 | Second Duplexer | 3 | 2.5 |

The unit of the component area is square millimeters (mm²). The circuit diagram 300 may further include other components. The sensitivities of other components not listed in Table 1 are all less than or equal to 2.

In the embodiment, the area reference value served as the determining criterion for the component area may be, for example, set as 100 mm². Therefore, the processor 110 classifies components whose areas are greater than or equal to 100 mm² and whose numbers are 1 to 6 as main components. Next, the processor 110 uses the minimum component sensitivity value 15 among the components numbered 1 to 6 as the connection reference value. Therefore, although the component area of number 7 is smaller than the area reference value 100 mm², the component sensitivity of the component numbered 7 is greater than the connection reference value 15, so the processor 110 still classifies the component numbered 7 as a main component.

Therefore, in step S200, the processor 110 converts the circuit diagram 300 into the netlist to obtain component sensitivity information. In step S210, the processor 110 sets the area reference value. In step S220, the processor 110 classifies the components (component numbers 1 to 6) whose component areas are greater than or equal to the area reference value as main components. The source of component area information is the component dimension table. In step S230, the processor 110 sets the component sensitivity minimum value 15 in the main components as the connection reference value. In step S240, the processor 110 classifies the component (component number 7) whose component sensitivity is greater than the connection reference value as a main component.

In step S230, although the processor 110 uses the component sensitivity minimum value in the main components in step S220 as the connection reference value which is the determining criterion for sensitivity, the disclosure is not limited thereto. In other embodiments, the connection reference value may be arbitrarily set.

Therefore, through the search method of the main component in FIG. 5, the processor 110 may find the main component in the circuit diagram 300. In an embodiment, the processor 110 classifies other components that are not main components as auxiliary components.

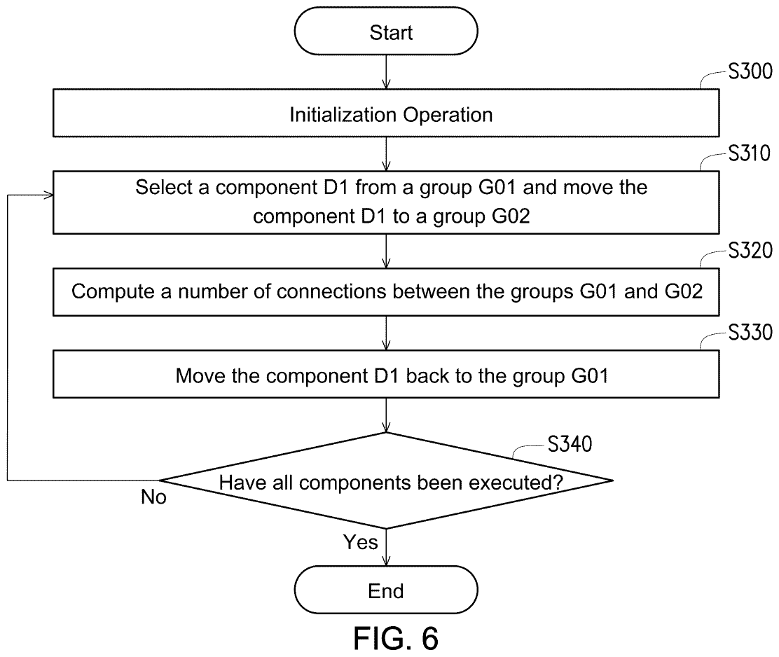

FIG. 6 is a flow chart of computation of a component sensitivity according to an embodiment of the disclosure. Please refer to FIG. 1, FIG. 3 and FIG. 6. In step S300, the processor 110 first performs an initialization operation. In the initialization operation, the processor 110 first sets two circuit groups, respectively named as groups G01 and G02. Next, the processor 110 moves all components in the netlist to the group G01.

In step S310, the processor 110 selects a component D1 from the group G01 and moves the component D1 to the group G02. In step S320, the processor 110 computes the number of connections between the groups G01 and G02. In step S330, the processor 110 moves the component D1 back to the group G01. In step S340, the processor 110 may confirm whether the components in the group G01 has been executed. If the execution has been completed, the processor 110 ends the computation process of component sensitivity. If the execution has not been completed, the processor 110 may return to step S310 to continue executing the computation process of component sensitivity. In this way, the processor 110 may obtain the sensitivity information of all components.

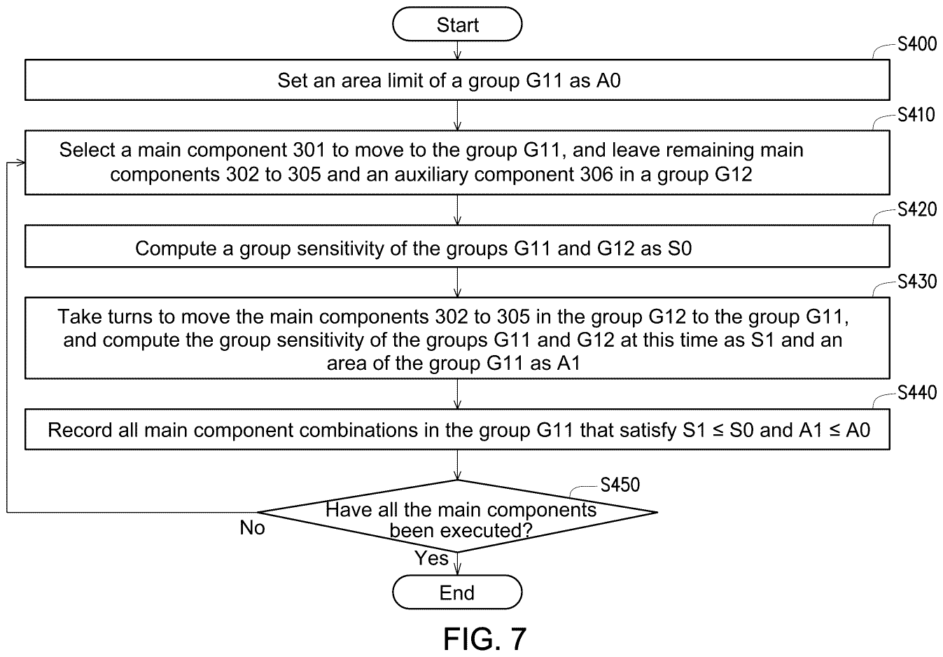

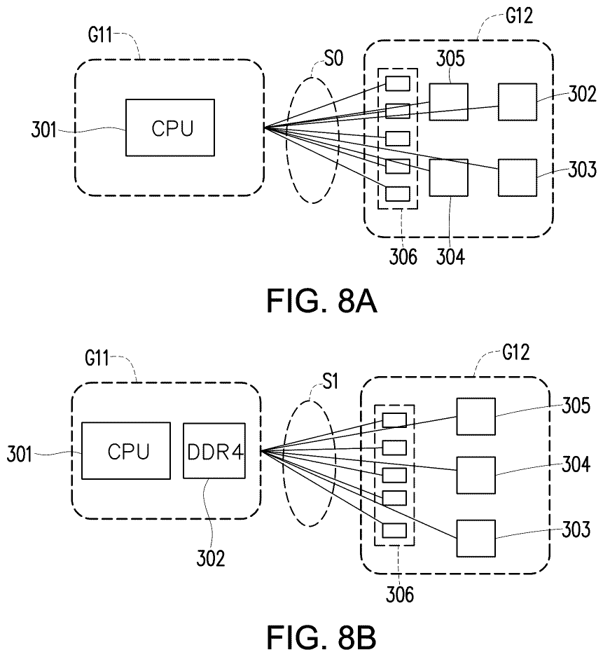

Next, the search method of the main component combination is illustrated. FIG. 7 is a step flow chart of a search method of a main component combination according to an embodiment of the disclosure. FIG. 8A and FIG. 8B are respectively schematic outline diagrams of different main component combinations in the embodiment of FIG. 7.

Please refer to FIG. 7, FIG. 8A and FIG. 8B. After the main components in the circuit diagram 300 are found, the processor 110 may further compute the group sensitivity of different main component combinations through the search method of the main component combination in FIG. 7. The processor 110 may obtain a list of all main components from the netlist. The sum of the quantities thereof is, for example, n, and two circuit groups are configured, which are respectively groups G11 and G12.

In step S400, the processor 110 sets the area limit of the group G11 as A0 to serve as a group area reference value. The area (that is, the value of A0) of the group G11 may be defined by the user, or there may be no limit. Next, the processor 110 moves all main components in the circuit diagram 300 to the group G12, and starts the loop for n times. In step S410, the processor 110 selects a main component 301 to move to the group G11, and leaves the remaining main components 302 to 305 and an auxiliary component 306 in the group G12, as shown in FIG. 8A. In step S420, the processor 110 computes the group sensitivity of the groups G11 and G12 at this time as S0 to serve as a group sensitivity reference value. In step S430, the processor 110 takes turns to move the main components 302 to 305 in the group G12 to the group G11, and computes the group sensitivity of the groups G11 and G12 as S1 and the area of the group G11 as A1, as shown in FIG. 8B. The area A1 of the group G11 is the sum of the areas of the components 301 and 302. The component area may be obtained from the component dimension information.

FIG. 8B takes moving the main component 302 to the group G11 as an example. The processor 110 may repeatedly execute step S430 to obtain the group sensitivity of the group G11 and G12 and the sum of the component areas in the group G11 when the other main components 303 to 305 and the main component 301 are in the group G11.

In step S440, the processor 110 may record all main component combinations in the group G11 that satisfy S1≤S0 and A1≤A0. That is to say, the processor 110 may take the electronic component combination in the group G11 whose group area A1 is smaller than the group area reference value A0 and whose group sensitivity S1 is less than the group sensitivity reference value S0 as the main component combination. In step S450, the processor 110 confirms whether all main components have been executed. If the execution has been completed, the processor 110 may end the search method of the main component combination in FIG. 7. If the execution has not been completed, the processor 110 may return to step S410 to continue executing the search method of the main component combination. In this way, the processor 110 may obtain the group sensitivity information of all main component combinations, which is the boundary condition related to a union combination of components in the second boundary condition.

The search method for the main component combination in FIG. 7 is further illustrated below. Different main component combinations may change the sensitivity between different circuit layers, which represents that the number of connections between circuit components in different layers also changes accordingly, and may also affect the characteristics of the circuit. Please refer to FIG. 8A and FIG. 8B, which shows that the circuit components are divided into the two groups G11 and G12. In the group G11 in FIG. 8A, only one main component 301 is placed, and the other main components 302 to 305 are all placed in the group G12. In this manner of partition, the sensitivity value between the groups G11 and G12 is 192, that is, S0=192. The two main components 301 and 302 are placed in the group G11 in FIG. 8B, and the remaining main components 302 to 305 are all placed in the group G12. In this manner of partition, the sensitivity value between the groups G11 and G12 is 60, that is, S1=60. It can be seen that whether certain main components in the circuit diagram are placed in the same group has a great impact on the changes in the sensitivity values.

Different circuits may have respective characteristic needs. The sensitivity value between circuit groups may need to be the lower the better, or the sensitivity value may be the higher the better, or even the expected sensitivity value is a fixed value. FIG. 7 is an example of the search algorithm of the main component combination, and is based on the expected circuit needs where the lower the sensitivity value the better.

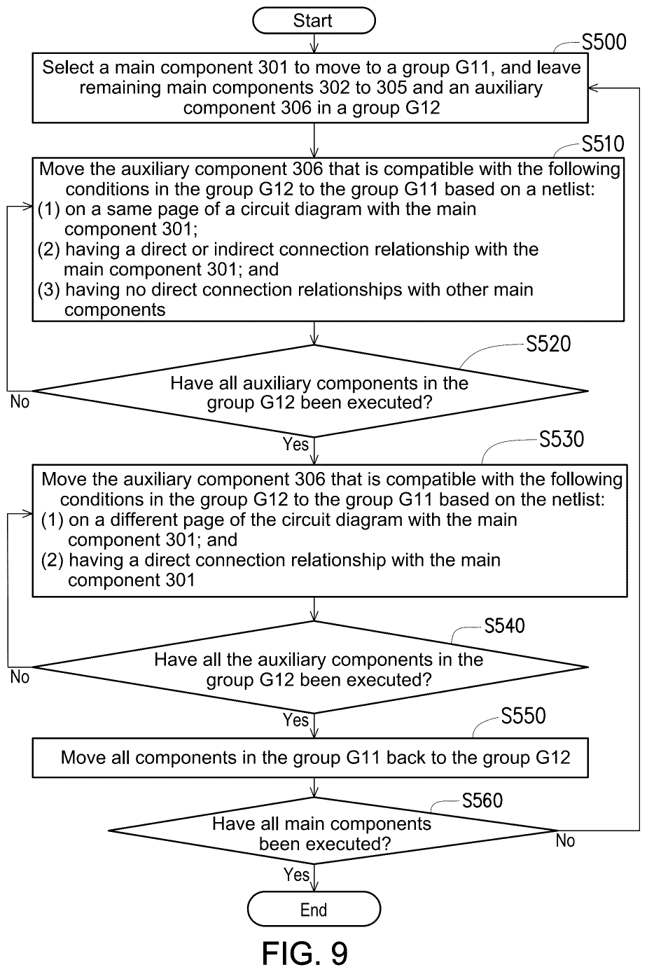

Next, the search method of the combination of the main component and the auxiliary component is illustrated. FIG. 9 is a step flow chart of a search method of a combination of a main component and an auxiliary component according to an embodiment of the disclosure.

Please refer to FIG. 9. After the main components in the circuit diagram 300 are found, the processor 110 may classify other components that are not the main components as auxiliary components. In an application, the auxiliary components need to be disposed in the same group as the main components. For example, the power pin of the main component 303 needs to be adjacently disposed with a decoupling capacitor to meet the needs for signal and power integrity (SI/PI). The processor 110 may find the combination of the main component and the auxiliary component through the search method in FIG. 9.

In step S500, the processor 110 selects a main component 301 (as an example of a first main component) to move to the group G11, and leaves the remaining main components 302 to 305 and the auxiliary component 306 in the group G12. In step S510, the processor 110 moves the auxiliary component 306 that meets the following conditions in the group G12 to the group G11 based on the netlist: (1) on the same page of the circuit diagram with the main component 301; (2) having a direct or indirect connection relationship with the main component 301; and (3) having no direct connection relationships with other main components.

In step S520, the processor 110 confirms whether all the auxiliary component 306 in the group G12 have been executed. If the execution has not been completed, the processor 110 may return to step S510 to continue executing step S510. If the execution has been completed, the processor 110 may execute step S530.

Next, in step S530, the processor 110 moves the auxiliary component 306 that meets the following conditions in the group G12 to the group G11 based on the netlist: (1) on a different page of the circuit diagram from the main component 301; and (2) having a direct connection relationship with the main component 301.

In step S540, the processor 110 confirms whether all the auxiliary component 306 in group G12 has been executed. If the execution has not been completed, the processor 110 may return to step S530 to continue executing step S530. If the execution has been completed, except for the main component 301, the remaining components in the group G11 at this time are all auxiliary components of the main component 301, and the processor 110 may execute step S550.

In step S550, the processor 110 moves all components in the group G11 back to the group G12. In step S560, the processor 110 confirms whether all main components have been executed. If the execution has not been completed, the processor 110 may return to step S500 to continue searching for auxiliary components of other main components. If the execution has been completed, the processor 110 may end the search method of the combination of the main component and the auxiliary component.

In this way, the processor 110 may obtain information of all combinations of the main components and the auxiliary components.

Through the foregoing setting method of the boundary condition, the search method of the main component, the search method of the main component combination, and the search method of the combination of the main component and the auxiliary component, the components partitioning method of the disclosure may obtain sensitivity information of various component combinations.

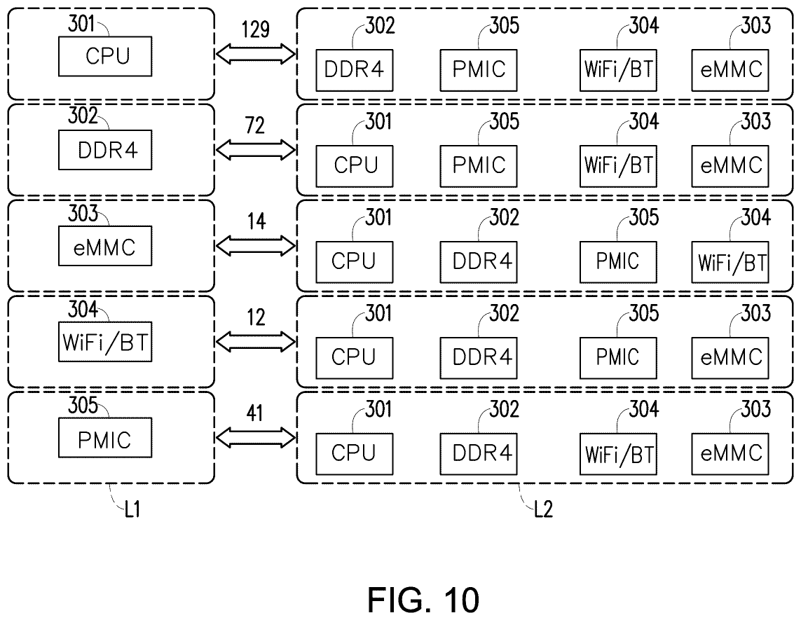

For example, the components partitioning method of the disclosure may find a smaller sensitivity value in different main component combinations between groups. Please refer to FIG. 10. FIG. 10 is a schematic outline diagram of main components located in different circuit layers according to an embodiment of the disclosure. In one of the embodiments with a circuit layer as a group, the values 129, 72, 14, 12, and 41 marked in FIG. 10 are the sensitivities between groups in different manners of layering. The values are not used to limit the disclosure.

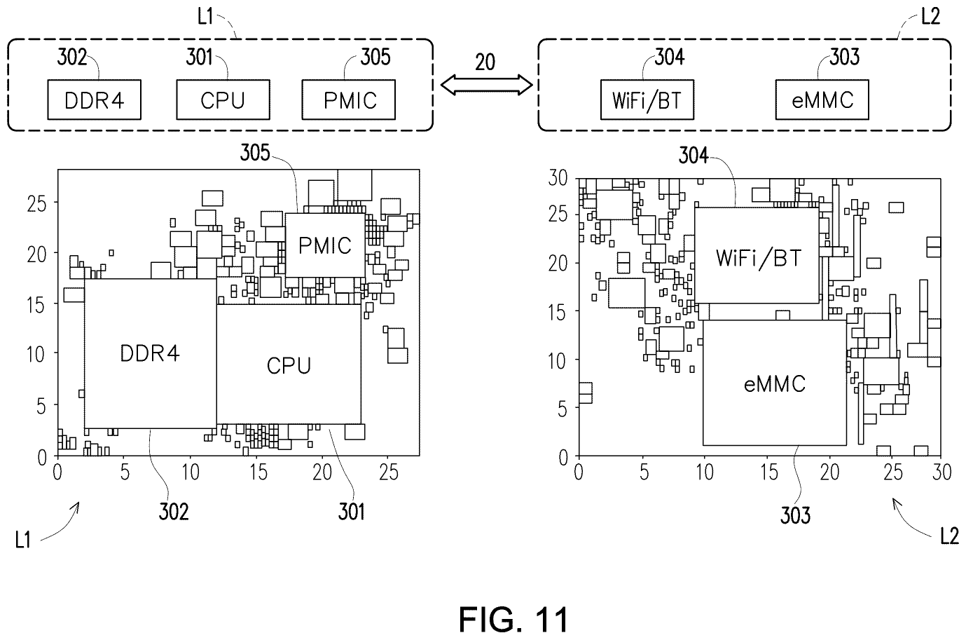

The processor 110 executes a separation operation on each main component, finds out the main components that are sensitive to “layering”, and unite the sensitive main components together. The main components 301, 302, and 305 with higher sensitivity values are components that are more sensitive to “layering”. Therefore, dividing the main components 301, 302, and 305 in the same layer may reduce the number of connections between layers, as shown in FIG. 11.

FIG. 11 is a schematic outline diagram where the main components 301, 302, and 305 are divided in a same layer according to an embodiment of the disclosure. Please refer to FIG. 11. Since the main components 301, 302, and 305 are all divided in a first layer L1, and the main components 303 and 304 are both divided in a second layer L2, the number of connections between layers may be reduced to 20. Therefore, through analyzing the component sensitivity, the processor 110 may find the main components that have a strong coupling relationship with each other. Moreover, the processor 110 may dispose the main components 301, 302, and 305 in the same layer through a union operation, and may dispose the main components 303 and 304 in another layer through a separation operation to achieve the result of partition. In this way, the processor 110 may optimize the number of connections between each circuit layer to allow the circuit to meet various demands.

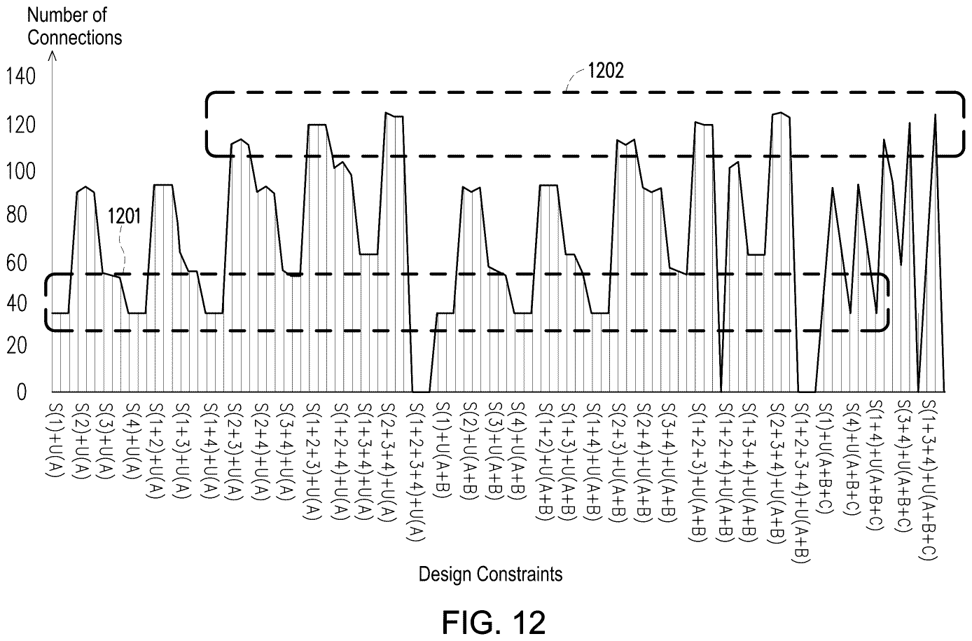

FIG. 12 is a schematic outline diagram of an embodiment of a boundary condition of the disclosure. The vertical axis is the number of connections between circuit layers. The horizontal axis is the design constraints. Please refer to FIG. 12 and Table 2 below:

TABLE 2

| | | | | |
|---|---|---|---|---|
| Separation | 1 | 2 | 3 | 4 |
| Combination | CPU, WiFi/BT | CPU, DDR4 | CPU, PMIC | CPU, eMMC |
| Union | | A | B | C |
| Combination | | DDR4 | WiFi/BT | PMIC |
| | | and other | and other | and other |
| | | auxiliary | auxiliary | auxiliary |
| | | components | components | components |

A separation combination 1 may be represented by S(1), which means that components CPU and WiFi/BT are disposed in different layers; a union combination A may be represented by U(A), which means that a component DDR and auxiliary components thereof are disposed in the same layer. The remaining separation combinations and union combinations may be deduced in the same way.

The processor 110 combines multiple main components to obtain the number of connections of different design constraints. The design constraints correspond to the combinations of multiple main components, such as AND or OR of the main components, or NOT part of the combinations of the main components. The number of connections of part of the design constraints in FIG. 12 is organized as Table 3 below:

TABLE 3

| | Number of |
|---|---|
| Design Constraint | Connections |
| S(2 + 3 + 4) + U(A) | 123 to 125 |
| S(2 + 3 + 4) + U(B) | |
| S(2 + 3 + 4) + U(C) | |
| S(1) + U(A), S(1) + U(A + B) | 35 |
| S(1) + U(B), S(1) + U(A + C) | |
| S(1) + U(C), S(1) + U(B + C) | |
| S(4) + U(A), S(4) + U(A + B) | |
| S(4) + U(B), S(4) + U(A + C) | |
| S(4) + U(C), S(4) + U(B + C) | |
| S(1 + 4) + U(A), S(1 + 4) + U(A + B) | |
| S(1 + 4) + U(B), S(1 + 4) + U(A + C) | |
| S(1 + 4) + U(C), S(1 + 4) + U(B + C) | |
| S(1) + U(A + B + C) | |
| S(4) + U(A + B + C) | |
| S(1 + 4) + U(A + B + C) | |

S(2+3+4) of the design constraint S(2+3+4)+U(A) means that the component CPU and the three components DDR4, PMIC, and eMMC are disposed on different layers. The “+” between S(2+3+4) and U(A) means a logic operation AND. It can be seen from Table 3 above, as long as the design constraint includes S(2), the number of connections between circuit layers may significantly increase. In addition, in FIG. 12, a dotted box 1201 represents that the number of connections of a corresponding design constraint is 35, and a dotted box 1202 represents that the number of connections of a corresponding design constraint is 135 to 140. Users may select the number of connections and the corresponding design constraint needed based on the analysis result to meet the needs.

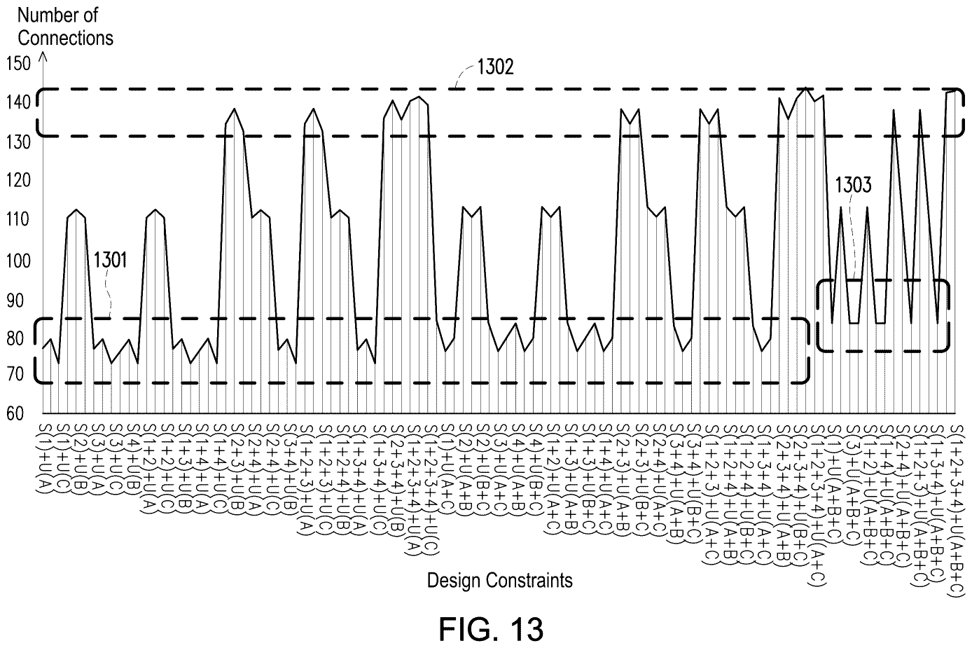

FIG. 13 is a schematic outline diagram of another embodiment of a boundary condition according to the disclosure. The number of connections of part of design constraints in FIG. 13 is organized as Table 4 below. Please refer to FIG. 13 and Table 4 below:

TABLE 4

| | Number of |
|---|---|
| Design Constraint | Connections |
| S(2) + U(A + B + C) | 113 to 143 |
| S(1 + 2) + U(A + B + C) | |
| S(2 + 3) + U(A + B + C) | |
| S(2 + 4) + U(A + B + C) | |
| S(1 + 2 + 3 + U(A + B + C) | |
| S(1 + 2 + 4) + U(A + B + C) | |
| S(2 + 3 + 4) + U(A + B + C) | |
| S(1 + 2 + 3 + 4) + U(A + B + C) | |
| S(1) + U(A + B + C) | 83 |
| S(3) + U(A + B + C) | |
| S(4) + U(A + B + C) | |
| S(1 + 3) + U(A + B + C) | |
| S(1 + 4) + U(A + B + C) | |
| S(3 + 4) + U(A + B + C) | |
| S(1 + 3 + 4) + U(A + B + C) | |
| S(1) + U(A + B + C) | |
| S(4) + U(A + B + C) | |
| S(1 + 4) + U(A + B + C) | |

It can be seen from Table 4 above, the component CPU and the component DDR4 are disposed in the same layer, and have better electrical characteristics of separation from other components. In addition, in FIG. 13, a dotted box 1301 represents that the number of connections of a corresponding design constraint is 70 to 80, and a dotted box 1302 represents that the number of connections of a corresponding design constraint is 135 to 140. Users may select the design constraint needed based on the analysis result to meet the needs. In an embodiment, the numbers of connections and the design constraints corresponding to a dotted box 1303 may be a manner of circuit design expected by the user.

In summary, according to the embodiment of the disclosure, the circuit components in the circuit diagram may be automatically partitioned through the components partitioning method to increase the efficiency and accuracy of component partitioning. In addition, the components partitioning method of the disclosure may effectively assist users in modular planning to allow the circuit design result to meet the expected product specification. If the circuit design result does not meet the expected product specification, the user may correspondingly adjust the boundary condition, improve product characteristics, and optimize product performance.

Although the disclosure has been disclosed in the above embodiments, the embodiments are not intended to limit the disclosure. Persons skilled in the art may make some changes and modifications without departing from the spirit and scope of the disclosure. Therefore, the protection scope of the disclosure shall be defined by the appended claims.

What is claimed is:

1. A components partitioning method, adapted to partition a plurality of electronic components in a circuit diagram, wherein the plurality of electronic components comprise a plurality of main components and a plurality of auxiliary components, and the components partitioning method comprises:
searching for the plurality of main components, a main component combination and the plurality of auxiliary components based on a netlist;
setting at least one boundary condition; and
partitioning the plurality of main components and the plurality of auxiliary components based on the at least one boundary condition and the netlist, wherein a boundary condition between each component group meets a set value.

2. The components partitioning method according to claim 1, further comprising:
providing the circuit diagram that has completed a functional design, and converting the circuit diagram into the netlist.

3. The components partitioning method according to claim 1, wherein steps of searching for the plurality of main components, the main component combination and the plurality of auxiliary components based on the netlist comprise:
classifying a plurality of electronic components whose numbers of connections between components are greater than a connection reference value as the plurality of main components.

4. The components partitioning method according to claim 3, wherein the steps of searching for the plurality of main components, the main component combination and the plurality of auxiliary components based on the netlist further comprise:
classifying other plurality of electronic components that are not the plurality of main components as the plurality of auxiliary components.

5. The components partitioning method according to claim 1, further comprising:
searching for the plurality of main components, the main component combination and the plurality of auxiliary components based on a component dimension table.

6. The components partitioning method according to claim 4, wherein steps of searching for the main component, the main component combination and the auxiliary component based on a component dimension table comprise:
classifying a plurality of electronic components whose component areas are larger than an area reference value as the plurality of main components.

7. The components partitioning method according to claim 1, wherein steps of searching for the plurality of main components, the main component combination and the plurality of auxiliary components based on the netlist comprise:
setting a group area reference value and a group sensitivity reference value;
dividing the plurality of main components into a plurality of groups; and
serving an electronic component combination in the plurality of groups whose group area is smaller than the group area reference value and whose group sensitivity is less than the group sensitivity reference value as the main component combination.

8. The components partitioning method according to claim 1, wherein the at least one boundary condition comprises a first boundary condition related to a number of connections, a second boundary condition related to a separation and a union of components, and/or a third boundary condition related to a partition area.

9. The components partitioning method according to claim 1, wherein the plurality of main components comprise a first main component, and steps of partitioning the plurality of main components and the plurality of auxiliary components based on the at least one boundary condition and the netlist comprise:
dividing a plurality of auxiliary components that meet the following conditions into a same group with the first main component: (1) on a same page of the circuit diagram with the first main component; (2) having is a direct or indirect connection relationship with the first main component; and (3) having no direct connection relationships with other plurality of main components.

10. The components partitioning method according to claim 9, wherein the steps of partitioning the plurality of main components and the plurality of auxiliary components based on the at least one boundary condition and the netlist further comprise:
dividing a plurality of auxiliary components that meet the following conditions into the same group with the first main component: (1) on a different page of the circuit diagram from the first main component; and (2) having the direct connection relationship with the first main component.

11. The components partitioning method according to claim 1, wherein the set value comprises a set value of an area, a set value of a number of connections, and a set value of a separation and a union of components.

12. A computer readable recording medium, comprising a computer program which commands a computer to execute the components partitioning method according to claim 1 after executing the computer program.

13. An electronic apparatus, adapted to partition a plurality of electronic components in a circuit diagram, wherein the plurality of electronic components comprise a plurality of main components and a plurality of auxiliary components, and the electronic apparatus comprises:
a storage component, configured to store a computer program; and
a processor, configured to search for the plurality of main components, a main component combination and the plurality of auxiliary components based on a netlist after executing the computer program, set at least one boundary condition, and partition the plurality of main components and the plurality of auxiliary components based on the at least one boundary condition and the netlist, wherein a boundary condition between each component group meets a set value.

14. The electronic apparatus according to claim 13, wherein the processor is further configured to provide the circuit diagram that has completed a functional design, and convert the circuit diagram into the netlist.

15. The electronic apparatus according to claim 13, wherein the processor classifies a plurality of electronic components whose numbers of connections between components are greater than a connection reference value as the plurality of main components.

16. The electronic apparatus according to claim 15, wherein the processor classifies other plurality of electronic components that are not the plurality of main components as the plurality of auxiliary components.

17. The electronic apparatus according to claim 13, wherein the processor is further configured to search for the plurality of main components, the main component combination and the plurality of auxiliary components based on a component dimension table.

18. The electronic apparatus according to claim 17, wherein the processor classifies a plurality of electronic components whose component areas are greater than an area reference value as the plurality of main components.

19. The electronic apparatus according to claim 13, wherein the processor is further configured to set a group area reference value and a group sensitivity reference value, divide the plurality of main components into a plurality of groups, and serve an electronic component combination in the plurality of groups whose group area is smaller than the group area reference value and whose group sensitivity is less than the group sensitivity reference value as the main component combination.

20. The electronic apparatus according to claim 13, wherein the at least one boundary condition comprises a first boundary condition related to a number of connections, a second boundary condition related to a separation and a union of components, and/or a third boundary condition related to a partition area.

21. The electronic apparatus according to claim 13, wherein the plurality of main components comprise a first main component, and the processor divides a plurality of auxiliary components that meet the following conditions into a same group with the first main component: (1) on a same page of the circuit diagram with the first main component; (2) having a direct or indirect connection relationship with the first main component; and (3) having no direct connection relationships with other plurality of main components.

22. The electronic apparatus according to claim 21, wherein the processor divides a plurality of auxiliary components that meet the following conditions into the same group with the first main component: (1) on a different page of the circuit diagram from the first main component; and (2) having a direct connection relationship with the first main component.

23. The electronic apparatus according to claim 13, wherein the set value comprises a set value of an area, a set value of a number of connections, and a set value of a separation and a union of components.
